(19) United States
(12) Patent Application Publication
(10) Pub. No.: US 2024/0321919 A1
(43) Pub. Date: Sep. 26, 2024

(54) SOLID-STATE IMAGING ELEMENT AND ELECTRONIC EQUIPMENT

(71) Applicant: SONY SEMICONDUCTOR SOLUTIONS CORPORATION, KANAGAWA (JP)

(72) Inventor: HIRONORI HOSHI, KANAGAWA (JP)

(21) Appl. No.: 18/580,257

(22) PCT Filed: Jun. 28, 2022
(86) PCT No.: PCT/JP2022/025792

§ 371 Date: Jan. 18, 2024

(30) Foreign Application Priority Data
Aug. 6, 2021 (JP) 2021-129791

(51) Int. Cl. H01L 27/146

(52) U.S. Cl. CPC H01L 27/14627; H01L 27/14645

(57) ABSTRACT

A solid-state imaging element (1) includes a first photoelectric conversion unit that includes a photoelectric conversion layer (52b) made of an organic material and photoelectrically converts light in a first wavelength region, a second photoelectric conversion unit and a third photoelectric conversion unit that are disposed on an opposite side of a light incident side with respect to the first photoelectric conversion unit and photoelectrically convert light in a second wavelength region and a third wavelength region different from the first wavelength region, and a first color splitter and a second color splitter that are disposed between the first photoelectric conversion unit and the second photoelectric conversion unit and the third photoelectric conversion unit and disperse light transmitted through the first photoelectric conversion unit. The first color splitter makes the light in the second wavelength region incident on the second photoelectric conversion unit near the first color splitter and bends the light in the third wavelength region toward the third photoelectric conversion unit adjacent to the first color splitter, and the second color splitter makes the light in the third wavelength region incident on the third photoelectric conversion unit near the second color splitter and bends the light in the second wavelength region toward the second photoelectric conversion unit adjacent to the second color splitter.

### FIELD

The present disclosure relates to a solid-state imaging element and electronic equipment.

### BACKGROUND

In recent years, there has been proposed a stacked image sensor in which a plurality of photoelectric conversion elements are stacked in a light incident direction. For example, there has been proposed a solid-state imaging element in which a photoelectric conversion unit that photoelectrically converts light in one wavelength region is provided on a light incident side and a photoelectric conversion unit that photoelectrically converts light in another wavelength region is provided on the opposite side of the light incident side (see, for example, Patent Literature 1.).

### CITATION LIST

### Patent Literature

Patent Literature 1: JP 2017-157801 A

### SUMMARY

### Technical Problem

However, in the related art described above, there is a problem that sensitivity is deteriorated in the photoelectric conversion unit on the opposite side of the light incident side because not a little light in another wavelength region is also absorbed in the photoelectric conversion unit on the light incident side.

Therefore, the present disclosure proposes a solid-state imaging element and electronic equipment capable of improving the sensitivity of a photoelectric conversion unit located on the opposite side of a light incident side.

### Solution to Problem

According to the present disclosure, there is provided a solid-state imaging element. The solid-state imaging element includes a first photoelectric conversion unit, a second photoelectric conversion unit, a third photoelectric conversion unit, a first color splitter and a second color splitter. The first photoelectric conversion unit includes a photoelectric conversion layer made of an organic material and photoelectrically converts light in a first wavelength region. The second photoelectric conversion unit is disposed on an opposite side of a light incident side with respect to the first photoelectric conversion unit and photoelectrically converts light in a second wavelength region different from the first wavelength region. The third photoelectric conversion unit is disposed side by side with the second photoelectric conversion unit and photoelectrically converts light in a third wavelength region different from the first wavelength region and the second wavelength region. The first color splitter is disposed between the first photoelectric conversion unit and the second photoelectric conversion unit and disperses light transmitted through the first photoelectric conversion unit. The second color splitter is disposed between the first photoelectric conversion unit and the third photoelectric conversion unit and disperses the light transmitted through the first photoelectric conversion unit. And the first color splitter makes the light in the second wavelength region incident on the second photoelectric conversion unit near the first color splitter and bends the light in the third wavelength region toward the third photoelectric conversion unit adjacent to the first color splitter. And the second color splitter makes the light in the third wavelength region incident on the third photoelectric conversion unit near the second color splitter and bends the light in the second wavelength region toward the second photoelectric conversion unit adjacent to the second color splitter.

### Advantageous Effects of Invention

According to the present disclosure, it is possible to provide a solid-state imaging element and electronic equipment capable of improving sensitivity of a photoelectric conversion unit located on the opposite side of a light incident side. Note that the effects described herein are not necessarily limited and may be any of the effects described in the present disclosure.

### BRIEF DESCRIPTION OF DRAWINGS

FIG. 1 is a system configuration diagram illustrating a schematic configuration example of a solid-state imaging element according to an embodiment of the present disclosure.

FIG. 2 is a sectional view schematically illustrating structure of a pixel array unit according to the embodiment of the present disclosure.

FIG. 3 is a diagram for explaining a principle of a color splitter according to the embodiment of the present disclosure.

FIG. 4 is a diagram illustrating an incident state of green light in the pixel array unit according to the embodiment of the present disclosure.

FIG. 5 is a diagram illustrating an incident state of red light in the pixel array unit according to the embodiment of the present disclosure.

FIG. 6 is a diagram illustrating an incident state of blue light in the pixel array unit according to the embodiment of the present disclosure.

FIG. 7 is a sectional view schematically illustrating another example of the structure of the pixel array unit according to the embodiment of the present disclosure.

FIG. 8 is a diagram illustrating an example of a manufacturing process for the color splitter according to the embodiment of the present disclosure.

FIG. 9 is a diagram illustrating the example of the manufacturing process for the color splitter according to the embodiment of the present disclosure.

FIG. 10 is a diagram illustrating the example of the manufacturing process for the color splitter according to the embodiment of the present disclosure.

FIG. 11 is a diagram illustrating the example of the manufacturing process for the color splitter according to the embodiment of the present disclosure.

FIG. 12 is a block diagram illustrating a configuration example of an imaging device functioning as electronic equipment to which a technique according to the present disclosure is applied.

### DESCRIPTION OF EMBODIMENTS

Embodiments of the present disclosure are explained in detail below with reference to the drawings. Note that, in the embodiments explained below, redundant explanation is omitted by denoting the same parts with the same reference numerals and signs.

In recent years, there has been proposed a stacked image sensor in which a plurality of photoelectric conversion elements are stacked in a light incident direction. For example, there has been proposed a solid-state imaging element in which a photoelectric conversion unit that photoelectrically converts light in one wavelength region is provided on a light incident side and a photoelectric conversion unit that photoelectrically converts light in another wavelength region is provided on the opposite side of the light incident side.

However, in the related art described above, there is a problem that sensitivity is deteriorated in the photoelectric conversion unit on the opposite side of the light incident side because not a little light in another wavelength region is also absorbed in the photoelectric conversion unit on the light incident side.

Therefore, it is expected to realize a technique that can overcome the problems described above and improving the sensitivity of the photoelectric conversion unit located on the opposite side of the light incident side.

### [Configuration of a Solid-State Imaging Element]

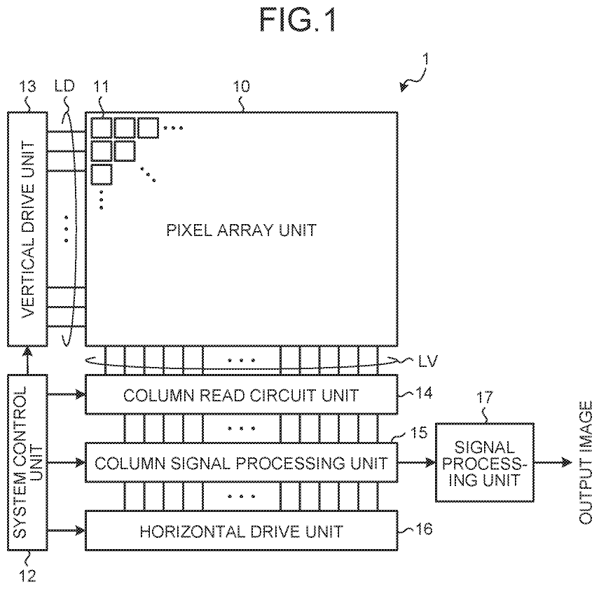

FIG. 1 is a system configuration diagram illustrating a schematic configuration example of a solid-state imaging element 1 according to an embodiment of the present disclosure. As illustrated in FIG. 1, the solid-state imaging element 1, which is a CMOS image sensor, includes a pixel array unit 10, a system control unit 12, a vertical drive unit 13, a column read circuit unit 14, a column signal processing unit 15, a horizontal drive unit 16, and a signal processing unit 17.

The pixel array unit 10, the system control unit 12, the vertical drive unit 13, the column read circuit unit 14, the column signal processing unit 15, the horizontal drive unit 16, and the signal processing unit 17 are provided on the same semiconductor substrate or on a plurality of electrically connected laminated semiconductor substrates.

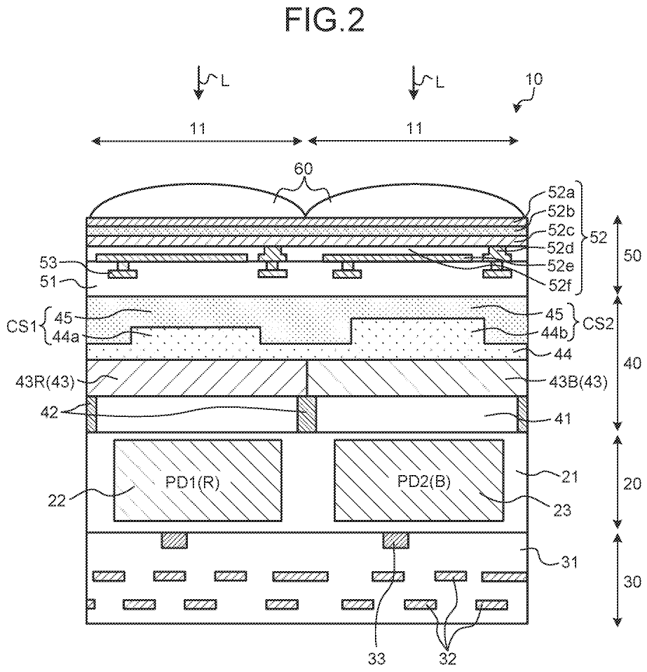

In the pixel array unit 10, effective unit pixels (hereinafter also referred to as “unit pixel”) 11 including photoelectric conversion elements (photoelectric conversion units 52 (see FIG. 2) or the like) capable of photoelectrically converting a charge amount corresponding to an incident light amount, accumulating the charge amount on the inside, and outputting the charge amount as a signal are two-dimensionally disposed in a matrix.

The pixel array unit 10 sometimes includes a region where dummy unit pixels having structure not including the photoelectric conversion unit 52, light-blocking unit pixels that shield light receiving surfaces from light to block light incidence from the outside, and the like are disposed in rows and/or columns besides the effective unit pixels 11.

Note that the light-blocking unit pixels may have the same configuration as the configuration of the effective unit pixel 11 except a structure in which the light-receiving surface is shielded from light. In the following explanation, photoelectric charges of a charge amount corresponding to an incident light amount are also simply referred to as “charges” and the unit pixels 11 are also simply referred to as “pixels”.

In the pixel array unit 10, pixel drive lines LD are formed for each of the rows in the left-right direction in the drawing (an array direction of pixels in pixel rows) and vertical pixel wires LV are formed for each of the columns in the up-down direction in the drawing (an array direction of pixels in pixel columns) with respect to the pixel array in a matrix. One ends of the pixel drive lines LD are connected to output ends corresponding to the rows of the vertical drive unit 13.

The column read circuit unit 14 includes at least a circuit that supplies a constant current to the unit pixels 11 in a selected row in the pixel array unit 10 for each of the columns and a current mirror circuit, a changeover switch for the unit pixel 11 to be read, and the like.

The column read circuit unit 14 configures an amplifier in conjunction with a transistor in the selected pixel in the pixel array unit 10, converts a photoelectric charge signal into a voltage signal, and outputs the voltage signal to the vertical pixel wires LV.

The vertical drive unit 13 includes a shift register and an address decoder and drives all the unit pixels 11 of the pixel array unit 10 simultaneously or drives the unit pixels 11 in units of rows. Although a specific configuration of the vertical drive unit 13 is not illustrated, the vertical drive unit 13 has a configuration including a read scanning system and a sweep scanning system or a batch sweeping and batch transfer system.

In order to read a pixel signal from the unit pixels 11, the read scanning system selectively scans the unit pixels 11 of the pixel array unit 10 in row units in order. In the case of row driving (a rolling shutter operation), about sweeping, sweep scanning is performed, earlier than read scanning by a time of shutter speed, on a read row on which the read scanning is performed by the read scanning system.

In the case of global exposure (a global shutter operation), batch sweeping is performed earlier than batch transfer by the time of the shutter speed. By such sweeping, unnecessary charges are swept (reset) from the photoelectric conversion unit 52 and the like of the unit pixel 11 in the read row. Then, a so-called electronic shutter operation is performed by sweeping (resetting) the unnecessary charges.

Here, the electronic shutter operation refers to an operation of discarding unnecessary photoelectric charges accumulated in the photoelectric conversion unit 52 or the like until immediately before and newly starting exposure (starting accumulation of photoelectric charges).

A signal read by the read operation by the read scanning system corresponds to an amount of light made incident after the immediately preceding read operation or electronic shutter operation. In the case of the row drive, a period from read timing by the immediately preceding read operation or sweep timing by the electronic shutter operation to read timing by the current read operation is a photoelectric charge storage time (exposure time) in the unit pixels 11. In the case of the global exposure, a time from the batch sweeping to the batch transfer is an accumulation time (an exposure time).

Pixel signals output from the unit pixels 11 of the pixel row selectively scanned by the vertical drive unit 13 are supplied to the column signal processing unit 15 through each of the vertical pixel wires LV. The column signal processing unit 15 performs predetermined signal processing on the pixel signals output from the unit pixels 11 of the selected row through the vertical pixel wires LV for each of the pixel columns of the pixel array unit 10 and temporarily retains the pixel signals after the signal processing.

Specifically, the column signal processing unit 15 performs at least noise removal processing, for example, CDS (Correlated Double Sampling) processing as the signal processing. By the CDS processing by the column signal processing unit 15, fixed pattern noise specific to pixels such as reset noise and threshold variation of an amplification transistor AMP is removed.

Note that the column signal processing unit 15 can be imparted with, for example, an AD conversion function besides the noise removal processing and configured to output a pixel signal as a digital signal.

The horizontal drive unit 16 includes a shift register and an address decoder and sequentially selects unit circuits corresponding to the pixel columns of the column signal processing unit 15. By the selective scanning by the horizontal drive unit 16, the pixel signals subjected to the signal processing by the column signal processing unit 15 are sequentially output to the signal processing unit 17.

The system control unit 12 includes a timing generator that generates various timing signals. The system control unit 12 performs drive control for the vertical drive unit 13, the column signal processing unit 15, the horizontal drive unit 16, and the like based on various timing signals generated by the timing generator.

The solid-state imaging element 1 further includes a signal processing unit 17 and a not-illustrated data storage unit. The signal processing unit 17 has at least an addition processing function and performs various kinds of signal processing such as addition processing on a pixel signal output from the column signal processing unit 15.

In the signal processing in the signal processing unit 17, the data storage unit temporarily stores data necessary for the processing. The signal processing unit 17 and the data storage unit may be an external signal processing unit provided on a substrate different from a substrate on which the solid-state imaging element 1 is provided, may perform, for example, processing by a DSP (Digital Signal Processor) or software, or may be mounted on the same substrate as the substrate on which the solid-state imaging element 1 is mounted.

### [Configuration of the Pixel Array Unit]

Subsequently, a detailed configuration of the pixel array unit 10 is explained with reference to FIG. 2 to FIG. 6. FIG. 2 is a sectional view schematically illustrating structure of the pixel array unit 10 according to the embodiment of the present disclosure.

The pixel array unit 10 includes a semiconductor layer 20, a wiring layer 30, an optical layer 40, an organic photoelectric conversion layer 50, and an on-chip lens (OCL) 60.

In the pixel array unit 10, the OCL 60, the organic photoelectric conversion layer 50, the optical layer 40, the semiconductor layer 20, and the wiring layer 30 are stacked in order from the side (hereinafter also referred to as light incident side) on which the incident light L from the outside is made incident.

The semiconductor layer 20 includes a semiconductor region 21 of a first conductivity type (for example, P-type) and semiconductor regions 22 and 23 of a second conductivity type (for example, N-type). Then, in the semiconductor region 21 of the first conductivity type, the semiconductor regions 22 and 23 of the second conductivity type are formed side by side in a plane direction (an array direction of the pixels 11) in units of pixels, whereby the photodiodes PD1 and PD2 by PN junction are formed side by side in the plane direction.

The photodiode PD1 is an example of a second photoelectric conversion unit and the photodiode PD2 is an example of a third photoelectric conversion unit.

For example, the photodiode PD1 including the semiconductor region 22 as a charge storage region is a photoelectric conversion unit that receives and photoelectrically converts light in a red wavelength region (hereinafter also referred to as “red region”). The red wavelength region (the red region) is an example of a second wavelength region.

The photodiode PD2 including the semiconductor region 23 as a charge storage region is a photoelectric conversion unit that receives and photoelectrically converts light in a blue wavelength region (hereinafter also referred to as “blue region”). The blue wavelength region (the blue region) is an example of a third wavelength region.

For example, the photodiode PD1 or the photodiode PD2 is individually formed for each of the pixels 11 of the pixel array unit 10.

The wiring layer 30 is disposed on the surface on the opposite side of the light incident side in the semiconductor layer 20. The wiring layer 30 is configured by forming a plurality of wiring films 32 and a plurality of pixel transistors 33 in an interlayer insulating film 31. The plurality of pixel transistors 33 perform reading of charges accumulated in the photodiodes PD1 and PD2 and a photoelectric conversion unit 52 explained below.

The optical layer 40 is disposed on the surface on the light incident side in the semiconductor layer 20. The optical layer 40 includes a planarization layer 41, a light blocking wall 42, a color filter 43, a low refractive index layer 44, and a high refractive index layer 45. In the optical layer 40, the high refractive index layer 45, the low refractive index layer 44, the color filter 43, and the planarization layer 41 (or the light blocking wall 42) are stacked in order from the light incident side.

The planarization layer 41 is provided in order to planarize a surface on which the color filter 43 is formed and to avoid unevenness caused in a rotational application process in forming the color filter 43. The planarization layer 41 is made of, for example, a silicon oxide.

Note that the planarization layer 41 is not limited to be made of the silicon oxide and may be made of a silicon nitride, an organic material (for example, acrylic resin), or the like.

The light blocking wall 42 is a wall-like film that blocks light obliquely made incident from an adjacent pixels 11. The light blocking wall 42 is provided to surround the photodiode PD1 or the photodiode PD2 in a plan view on the inside of the planarization layer 41. The light blocking wall 42 is made of, for example, aluminum, tungsten, or the like.

The color filter 43 is an optical filter that transmits light in a predetermined wavelength region in the incident light L. The color filter 43 includes, for example, a color filter 43R that transmits light in the red region and a color filter 43B that transmits light in the blue region.

The color filter 43R is an example of a first color filter and is disposed on the light incident side of the photodiode PD1. The color filter 43B is an example of a second color filter and is disposed on the light incident side of the photodiode PD2. For example, the color filter 43R or the color filter 43B is individually formed for each of the pixels 11 of the pixel array unit 10.

The low refractive index layer 44 is made of a material having a refractive index lower than that of the high refractive index layer 45. The low refractive index layer 44 is made of, for example, a metal oxide such as a silicon oxide or an aluminum oxide or an organic substance such as acrylic resin.

A convex portion 44a and a convex portion 44b having a predetermined shape are provided on a surface on the light incident side of the low refractive index layer 44. The convex portion 44a is disposed on the light incident side of the photodiode PD1. The convex portion 44b is disposed on the light incident side of the photodiode PD2.

The high refractive index layer 45 is made of a material having a refractive index higher than that of the low refractive index layer 44. The high refractive index layer 45 is made of, for example, a silicon compound such as a silicon nitride or a silicon carbide, a metal oxide such as a titanium oxide, a tantalum oxide, a niobium oxide, a hafnium oxide, an indium oxide, or a tin oxide, or a composite oxide thereof. The high refractive index layer 45 may be made of an organic substance such as siloxane.

In the optical layer 40, a color splitter CS1 configured by the convex portion 44a of the low refractive index layer 44 and the high refractive index layer 45 adjacent to the convex portion 44a is disposed on the light incident side of the photodiode PD1. The color splitter CS1 is an example of a first color splitter.

In the optical layer 40, a color splitter CS2 configured by the convex portion 44b of the low refractive index layer 44 and the high refractive index layer 45 adjacent to the convex portion 44b is disposed on the light incident side of the photodiode PD2. The color splitter CS2 is an example of a second color splitter. Action and the like of the color splitters CS1 and CS2 are explained below.

The organic photoelectric conversion layer 50 is disposed on a surface on the light incident side of the optical layer 40. The organic photoelectric conversion layer 50 includes an interlayer insulating film 51 and a photoelectric conversion unit 52. The photoelectric conversion unit 52 is an example of a first photoelectric conversion unit. In the organic photoelectric conversion layer 50, the photoelectric conversion unit 52 and the interlayer insulating film 51 are stacked in order from the light incident side.

The interlayer insulating film 51 includes, for example, a single-layer film made of one kind among a silicon oxide, TEOS, a silicon nitride, a silicon oxynitride, and the like or a stacked film made of two or more of these.

The photoelectric conversion unit 52 includes an upper electrode 52a, a photoelectric conversion layer 52b, a charge storage layer 52c, lower electrodes 52d and 52e, and an insulating layer 52f. In the photoelectric conversion unit 52, the upper electrode 52a, the photoelectric conversion layer 52b, the charge storage layer 52c, the insulating layer 52f, and the lower electrodes 52d and 52e are stacked in order from the light incident side.

The upper electrode 52a, the photoelectric conversion layer 52b, the charge storage layer 52c, and the insulating layer 52f are formed in common for all the pixels 11 of the pixel array unit 10, for example, and the lower electrodes 52d and 52e are formed, for example, separately for each of the pixels 11 of the pixel array unit 10.

The upper electrode 52a is electrically connected to the wiring film 32 of the wiring layer 30 via a wiring layer or a through electrode (both not illustrated) or the like at the peripheral edge portion of the pixel array unit 10. As a material of the upper electrode 52a, for example, a transparent conductive material such as an indium tin oxide (ITO) is used.

The material of the upper electrode 52a and the lower electrode 52d is not limited to the ITO and various transparent conductive materials (for example, a tin oxide, a zinc oxide, IZO, IGO, IGZO, ATO, and AZO) and the like can be used.

Note that the IZO is an oxide obtained by adding indium to zinc oxide, the IGO is an oxide obtained by adding indium to a gallium oxide, and the IGZO is an oxide obtained by adding indium and gallium to a zinc oxide. The ATO is an oxide obtained by adding antimony to a tin oxide and the AZO is an oxide obtained by adding antimony to a zinc oxide.

The photoelectric conversion layer 52b is made of an organic semiconductor material and photoelectrically converts light in a selective wavelength region (for example, a green wavelength region (hereinafter also referred to as “green region”)) in the incident light L from the outside. The green wavelength region (the green region) is an example of a first wavelength region.

The photoelectric conversion layer 52b desirably includes one or both of a p-type organic semiconductor and an n-type organic semiconductor. The photoelectric conversion layer 52b is made of, for example, quinacridone, a quinacridone derivative, subphthalocyanine, a subphthalocyanine derivative, or the like and desirably contains at least one of these materials.

Note that the photoelectric conversion layer 52b is not limited to such a material and may be, for example, at least one kind of naphthalene, anthracene, phenanthrene, tetracene, pyrene, perylene, fluoranthene, and the like (all including derivatives).

For the photoelectric conversion layer 52b, a polymer or a derivative of phenylenevinylene, fluorene, carbazole, indole, pyrene, pyrrole, picoline, thiophene, acetylene, diacetylene, or the like may be used.

For the photoelectric conversion layer 52b, a metal complex dye, a cyanine dye, a merocyanine dye, a phenylxanthene dye, a triphenylmethane dye, a rhodacyanine dye, a xanthene dye, or the like may be used.

Note that examples of the metal complex dye include a dithiol metal complex dye, a metal phthalocyanine dye, a metal porphyrin dye, and a ruthenium complex dye. The photoelectric conversion layer 52b may contain other organic materials such as fullerene (C₆₀) and BCP (Bathocuproine) in addition to such an organic semiconductor dye.

When green light is photoelectrically converted by the photoelectric conversion layer 52b, for example, a rhodamine-based dye, a melacyanine-based dye, a quinacridone derivative, a subphthalocyanine-based dye (subphthalocyanine derivative), or the like can be used for the photoelectric conversion layer 52b.

The charge storage layer 52c is provided between the photoelectric conversion layer 52b and the insulating layer 52f and stores charges generated in the photoelectric conversion layer 52b. The charge storage layer 52c is preferably formed using a material having higher charge mobility and a larger band gap than the photoelectric conversion layer 52b.

For example, the band gap of the constituent material of the charge storage layer 52c is preferably 3.0 eV or more. Examples of such a material include an oxide semiconductor material such as IGZO and an organic semiconductor material.

Examples of the organic semiconductor material include transition metal dichalcogenides, unit silicon (SiC), diamond, graphene, carbon nanotubes, fused polycyclic hydrocarbon compounds, and fused heterocyclic compounds.

By providing such a charge storage layer 52c below the photoelectric conversion layer 52b, it is possible to prevent recombination of charges at the time of charge storage and improve transfer efficiency.

As the material of the lower electrodes 52d and 52e, the same material as that of the upper electrode 52a (for example, ITO) is used. The lower electrode 52d is electrically connected to the charge storage layer 52c and is electrically connected to a metal wire (not illustrated) piercing through the interlayer insulating film 51, the optical layer 40, and the semiconductor layer 20.

Such a metal wire is formed using a material such as tungsten (W), titanium (Ti), aluminum (Al), or copper (Cu). Note that the metal wire also functions as an inter-pixel light blocking film.

The metal wire is electrically connected to a charge storage unit (not illustrated) formed in the vicinity of the interface on the opposite side of the light incident side of the semiconductor region 21. The charge storage unit is formed of a semiconductor region of a second conductivity type (for example, N-type).

The lower electrode 52e is electrically connected to the wiring film 32 of the wiring layer 30 via a wiring film 53 formed in the interlayer insulating film 51, a through electrode (not illustrated), or the like.

Charges generated by photoelectric conversion in the photoelectric conversion unit 52 is transferred to the charge storage unit via the metal wire. The charge storage unit temporarily stores the charges photoelectrically converted by the photoelectric conversion unit 52 until the charges are read by the pixel transistor 33 corresponding to the charge storage unit.

Specifically, in the photoelectric conversion unit 52, a predetermined voltage is applied from a not-illustrated drive circuit to the lower electrodes 52d and 52e and the upper electrode 52a in a charge storage period. For example, in the charge storage period, a positive voltage is applied to the lower electrodes 52d and 52e, and a negative voltage is applied to the upper electrode 52a. Further, in the charge storage period, a larger positive voltage is applied to the lower electrode 52e than to the lower electrode 52d.

Consequently, in the charge storage period, electrons included in the charges generated by photoelectric conversion in the photoelectric conversion layer 52b are attracted by the large positive voltage of the lower electrode 52e and stored in the charge storage layer 52c.

In the pixel 11, a reset operation is performed by causing a not-illustrated reset transistor to operate in a later stage of the charge storage period. Consequently, the potential of the charge storage unit is reset and the potential of the charge storage unit becomes a power supply voltage.

In the pixel 11, a charge transfer operation is performed after the reset operation is completed. In the charge transfer operation, a positive voltage higher than that of the lower electrode 52e is applied from the drive circuit to the lower electrode 52d. Consequently, the electrons stored in the charge storage layer 52c are transferred to the charge storage unit via the lower electrode 52d and a metal wire 24.

In the pixel 11, a series of operations such as a charge storage operation, a reset operation, and a charge transfer operation is completed by the above operation.

The OCL 60 formed in a hemispherical shape is, for example, a lens that is provided for each of the pixels 11 and condenses the incident light L on the photoelectric conversion units 52, the photodiodes PD1, and the photodiodes PD2 of the pixels 11. The OCL 60 is made of, for example, acrylic resin or the like.

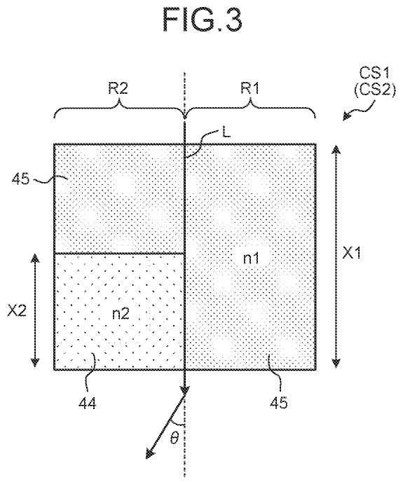

Subsequently, a principle of the color splitters CS1 and CS2 according to the embodiment is explained with reference to FIG. 3. FIG. 3 is a diagram for explaining the principle of the color splitters CS1 and CS2 according to the embodiment of the present disclosure.

As illustrated in FIG. 3, in the color splitters CS1 and CS2, a first region R1 and a second region R2 differently disposed in the depth direction of the low refractive index layer 44 and the high refractive index layer 45 are disposed.

Specifically, in the first region R1, the high refractive index layer 45 having a high refractive index (for example, refractive index n1) is disposed by length X1 in the light incident direction. In the second region R2, in addition to the high refractive index layer 45, the low refractive index layer 44 having a low refractive index (for example, refractive index n2) is disposed by length X2 in the light incident direction.

In the color splitters CS1 and CS2 having such a configuration, when the incident light L is simultaneously made incident on the first region R1 and the second region R2, a difference occurs in a traveling distance of the incident light L between the first region R1 and the second region R2 because of the refractive index difference between the low refractive index layer 44 and the high refractive index layer 45.

Specifically, an optical path length D1 in the first region R1 is calculated by the following Expression (1).

$$D 1 = n 1 \times X 1 \qquad ( 1 )$$

An optical path length D2 in the second region R2 is calculated by the following Expression (2).

$$D 2 = n 1 \times ( X 1 - X 2 ) + n 2 \times X 2 \qquad ( 2 )$$

Based on Expressions (1) and (2), an optical path length difference. AD between the first region R1 and the second region R2 is calculated by the following Expression (3).

$$Δ D = D 1 - D 2 = X 2 \times ( n 1 - n 2 ) \qquad ( 3 )$$

The incident light L having passed through the color splitters CS1 and CS2 is bent and emitted to the second region R2 side, to which light travels with a delay, as illustrated in FIG. 3 by an optical path length difference ΔD between the first region R1 and the second region R2.

A bending angle θ of such incident light L is calculated by the following Expression (4).

$$θ = arc tan ( Δ D / λ ) = arc tan ( X 2 \times ( n 1 - n 2 ) / λ ) \qquad ( 4 )$$

λ: wavelength of the incident light L

As shown in the above Expression (4), the bending angle θ of the incident light L depends on a wavelength λ of the incident light L. Therefore, by appropriately selecting the refractive indexes n1 and n2 of the low refractive index layer 44 and the high refractive index layer 45 according to the wavelength regions of the red region and the blue region, the color splitters CS1 and CS2 can bend the light in the respective wavelength regions in desired different directions.

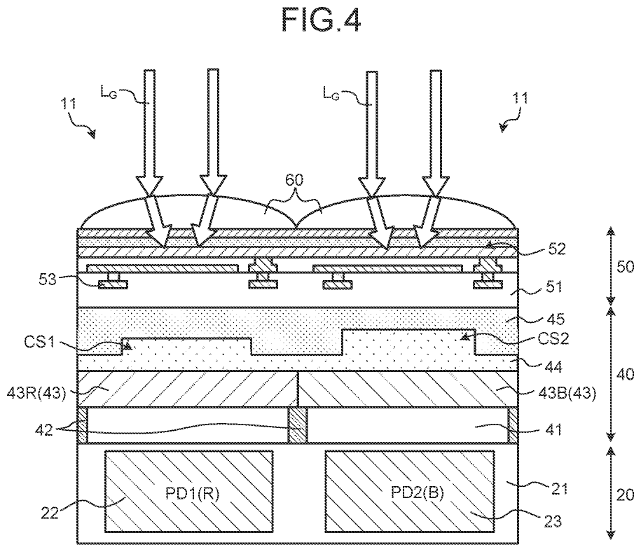

FIG. 4 is a diagram illustrating an incident state of green light L_{G} in the pixel array unit 10 according to the embodiment of the present disclosure. As illustrated in FIG. 4, the green light L_{G} in the green wavelength region is absorbed by the photoelectric conversion unit 52 located closest to the light incident side among the plurality of photoelectric conversion units and is photoelectrically converted by the photoelectric conversion unit 52.

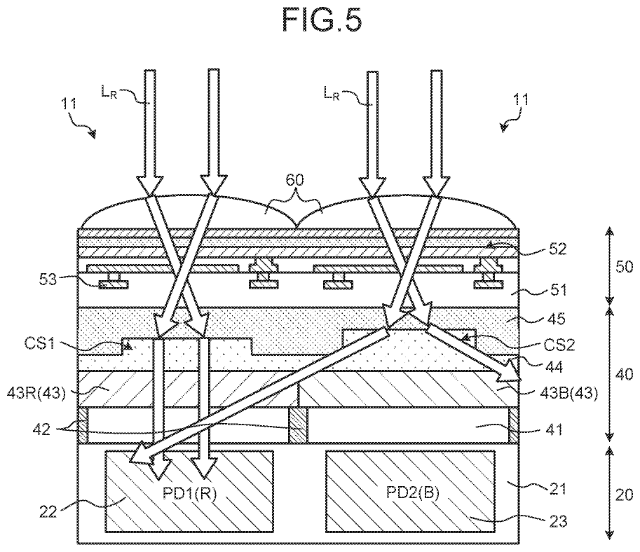

FIG. 5 is a diagram illustrating an incident state of red light L_{R} in the pixel array unit 10 according to the embodiment of the present disclosure. As illustrated in FIG. 5, the red light L_{R} in the red wavelength region is partially absorbed by the photoelectric conversion unit 52 located closest to the light incident side among the plurality of photoelectric conversion units and the rest is transmitted. The red light L_{R} transmitted through the photoelectric conversion unit 52 reaches the color splitters CS1 and CS2 in the optical layer 40.

Here, in the embodiment, as illustrated in FIG. 5, the color splitter CS1 makes the red light L_{R} incident on the photodiode PD1 closer to (that is, present right below) the color splitter CS1. In other words, in the color splitter CS1 according to the embodiment, a bending angle θ is controlled such that the incident red light L_{R} travels to the photodiode PD1 present right below the color splitter CS1.

In the embodiment, the color splitter CS2 makes the red light L_{R} incident on the photodiode PD1 adjacent to (that is, next to the photodiode PD2 present right below the color splitter CS2). In other words, in the color splitter CS2 according to the embodiment, the bending angle θ is controlled such that the incident red light L_{R} travels to the photodiode PD1 adjacent to the color splitter CS2.

That is, in the embodiment, in addition to the red light L_{R} made incident on the OCL 60 present immediately above the photodiode PD1, the red light L_{R} made incident on the OCL 60 adjacent to the photodiode PD1 can also be made incident on the photodiode PD1. Therefore, in the embodiment, the sensitivity of the photodiode PD1 that photoelectrically converts the red light L_{R} can be improved.

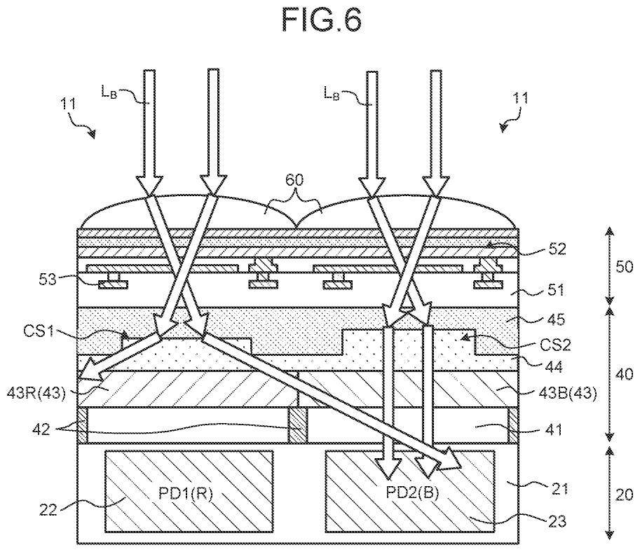

FIG. 6 is a diagram illustrating an incident state of blue light L_{B} in the pixel array unit 10 according to the embodiment of the present disclosure. As illustrated in FIG. 6, a part of the blue light L_{B} in a blue wavelength region is absorbed by the photoelectric conversion unit 52 located closest to the light incident side among the plurality of photoelectric conversion units and the rest is transmitted. The blue light L_{B} transmitted through the photoelectric conversion unit 52 reaches the color splitters CS1 and CS2 in the optical layer 40.

Here, in the embodiment, as illustrated in FIG. 6, the color splitter CS2 makes the blue light L_{B} incident on the photodiode PD2 closer to (that is, present right below) the color splitter CS2. In other words, in the color splitter CS2 according to the embodiment, the bending angle θ is controlled such that the incident blue light L_{B} travels to the photodiode PD2 present right below the color splitter CS2.

In the embodiment, the color splitter CS1 makes the blue light L_{B} incident on the photodiode PD2 adjacent to (that is, next to the photodiode PD1 present right below) the color splitter CS1. In other words, in the color splitter CS1 according to the embodiment, the bending angle θ is controlled such that the incident blue light L_{B} travels to the photodiode PD2 adjacent to the color splitter CS1.

That is, in the embodiment, in addition to the blue light L_{B} made incident on the OCL 60 present right above the photodiode PD2, the blue light L_{B} made incident on the OCL 60 adjacent to the photodiode PD2 can also be made incident on the photodiode PD2. Therefore, in the embodiment, the sensitivity of the photodiode PD2 that photoelectrically converts the blue light L_{B} can be improved.

As explained above, in the embodiment, by disposing the color splitters CS1 and CS2 between the photoelectric conversion unit 52 and the photodiodes PD1 and PD2, the sensitivity of the photodiodes PD1 and PD2 located on the opposite side of the light incident side can be improved.

In the embodiment, the color splitters CS1 and CS2 desirably have a meta-surface structure. Such a meta-surface structure is structure in which the plurality of convex portions 44a and 44b (see FIG. 2) formed in one color splitters CS1 and CS2 are arrayed at a period equal to or smaller than the wavelength λ of the incident light L.

Consequently, since the effective refractive indexes of the color splitters CS1 and CS2 can be changed, the light in the wavelength regions of each of the red region and the blue region can be further bent in a desired direction.

Therefore, according to the embodiment, the sensitivity of the photodiodes PD1 and PD2 located on the opposite side of the light incident side can be further improved.

In the embodiment, the color filter 43R is desirably disposed between the color splitter CS1 and the photodiode PD1 and the color filter 43B is desirably disposed between the color splitter CS2 and the photodiode PD2.

By disposing the color filters 43R and 43B having better spectral characteristics than the color splitters CS1 and CS2 in this way, occurrence of color mixture in the photodiodes PD1 and PD2 can be suppressed.

In the embodiment, among the plurality of photoelectric conversion units, the photoelectric conversion unit 52 on the light incident side desirably photoelectrically converts the light in the green region and the photodiodes PD1 and PD2 on the opposite side of the light incident side desirably photoelectrically convert the light in the red region and the blue region.

Consequently, the incident light L reaching the photodiodes PD1 and PD2 can be dispersed in advance by the photoelectric conversion unit 52 into light having a longer wavelength than the green region (that is, the red light L_{R}) and light having a shorter wavelength than the green region (that is, blue light L_{B}).

Therefore, according to the embodiment, occurrence of color mixture in the photodiodes PD1 and PD2 can be suppressed.

In the embodiment, the light blocking wall 42 is desirably disposed between the color filter 43, and the photodiodes PD1 and PD2. Consequently, it is possible to prevent incidence of light in a wavelength region other than a desired wavelength region in light transmitted through the color filters 43 of the adjacent pixels 11.

Therefore, according to the embodiment, occurrence of color mixture in the photodiodes PD1 and PD2 can be suppressed.

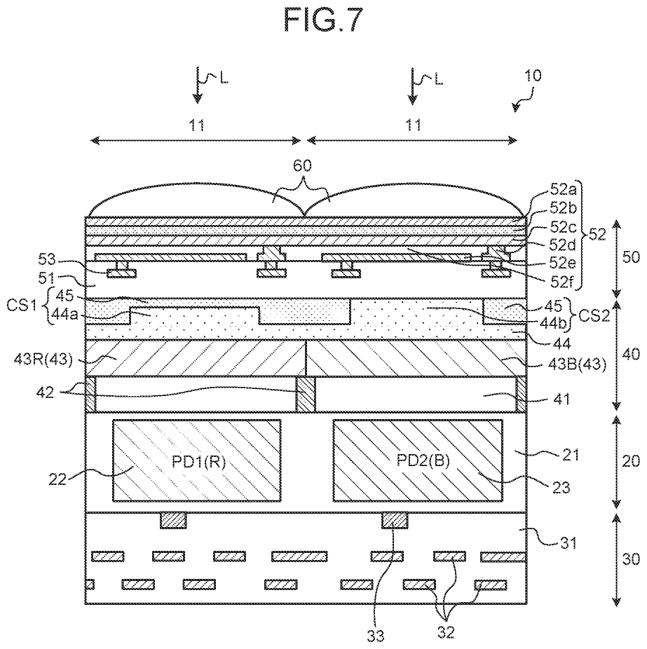

FIG. 7 is a sectional view schematically illustrating another example of the structure of the pixel array unit 10 according to the embodiment of the present disclosure. As illustrated in FIG. 7, the pixel array unit 10 of the other example includes the semiconductor layer 20, the wiring layer 30, the optical layer 40, the organic photoelectric conversion layer 50, and the on-chip lens (OCL) 60 as in the embodiment explained above.

On the other hand, in this other example, the configuration of the optical layer 40 is different from that in the embodiment explained above. Specifically, among the convex portions formed on the surface on the light incident side in the low refractive index layer 44 and configuring the color splitter, the surface on the light incident side in the thickest convex portion (the convex portion 44b in the figure) is in contact with the interlayer insulating film 51 of the organic photoelectric conversion layer 50 rather than the high refractive index layer 45.

Note that, among the convex portions formed on the surface on the light incident side in the low refractive index layer 44 and configuring the color splitter, the surface on the light incident side in the convex portion (the convex portion 44a in the figure) other than the thickest convex portion is in contact with the high refractive index layer 45 as in the embodiment explained above.

Even with such a configuration, by disposing the color splitters CS1 and CS2 between the photoelectric conversion unit 52 and the photodiodes PD1 and PD2, the sensitivity of the photodiodes PD1 and PD2 located on the opposite side of the light incident side can be improved.

In this other example, since the high refractive index layer 45 is not disposed between the convex portion 44b having a low refractive index and the interlayer insulating film 51 having a low refractive index in the photodiode PD2, it is possible to suppress reflection of light made incident on the color splitter CS2.

Therefore, according to the other example, the sensitivity of the photodiode PD2 can be further improved.

### [Manufacturing Process for the Color Splitters]

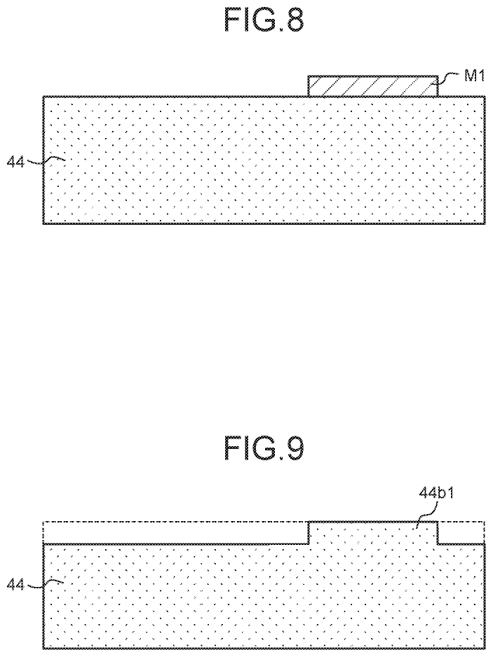

Subsequently, an example of a manufacturing process for the color splitters CS1 and CS2 according to the embodiment is explained with reference to FIG. 8 to FIG. 11. FIG. 8 to FIG. 11 are diagrams illustrating an example of a manufacturing process for the color splitters CS1 and CS2 according to the embodiment of the present disclosure.

In the manufacturing process for the color splitters CS1 and CS2, as illustrated in FIG. 8, first, the low refractive index layer 44 is formed on the surface of the color filter 43 (see FIG. 2) by a conventionally known method. Then, a mask layer M1 patterned into a predetermined plane shape is formed, by a conventionally known method, in a part where the convex portion 44b (see FIG. 11) is disposed on the surface of the low refractive index layer 44.

Next, as illustrated in FIG. 9, the surface of the low refractive index layer 44 is etched by a conventionally known method. Consequently, a convex portion 44b1, which is a part of the convex portion 44b (see FIG. 11), is formed on the surface of the low refractive index layer 44. Then, the mask layer M1 formed on the surface of the low refractive index layer 44 is removed by a conventionally known method.

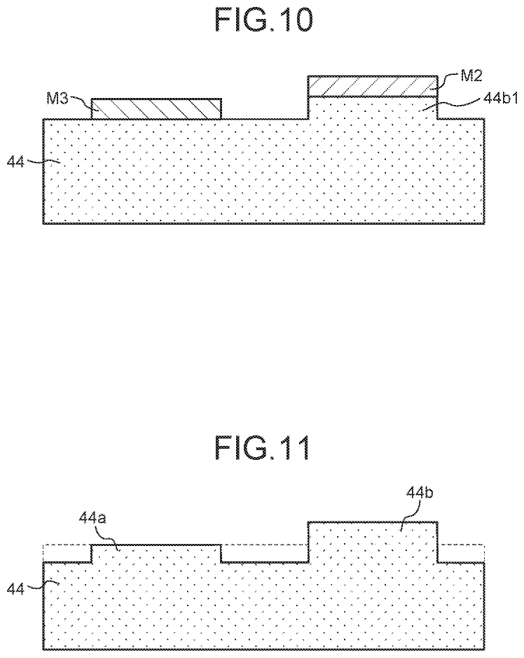

Next, as illustrated in FIG. 10, a mask layer M2 patterned into a predetermined plane shape is formed on the surface of the convex portion 44b1 by a conventionally known method. A mask layer M3 patterned into a predetermined plane shape is formed, by a conventionally known method, in a part where the convex portion 44a (see FIG. 11) is disposed on the surface of the low refractive index layer 44.

Next, as illustrated in FIG. 11, the surface of the low refractive index layer 44 is etched by a conventionally known method. Consequently, the convex portions 44a and 44b are formed on the surface of the low refractive index layer 44.

Further, the color splitters CS1 and CS2 according to the embodiment are formed by forming, with a conventionally known method, the high refractive index layer 45 (see FIG. 2) on the surface of the low refractive index layer 44 on which the convex portions 44a and 44b are formed.

### Effects

The solid-state imaging element 1 according to the embodiment includes the first photoelectric conversion unit (the photoelectric conversion unit 52), the second photoelectric conversion unit (the photodiode PD1), the third photoelectric conversion unit (the photodiode PD2), the first color splitter (the color splitter CS1), and the second color splitter (the color splitter CS2). The first photoelectric conversion unit (the photoelectric conversion unit 52) includes the photoelectric conversion layer 52b made of an organic material and photoelectrically converts light in the first wavelength region (the green region). The second photoelectric conversion unit (the photodiode PD1) is disposed on the opposite side of the light incident side with respect to the first photoelectric conversion unit (the photoelectric conversion unit 52) and photoelectrically converts light in the second wavelength region (the red region) different from the first wavelength region (the green region). The third photoelectric conversion unit (the photodiode PD2) is disposed side by side with the second photoelectric conversion unit (the photodiode PD1) and photoelectrically converts light in the third wavelength region (the blue region) different from the first wavelength region (the green region) and the second wavelength region (the red region). The first color splitter (the color splitter CS1) is disposed between the first photoelectric conversion unit (the photoelectric conversion unit 52) and the second photoelectric conversion unit (the photodiode PD1) and disperses light transmitted through the first photoelectric conversion unit (the photoelectric conversion unit 52). The second color splitter is disposed between the first photoelectric conversion unit (the photoelectric conversion unit 52) and the third photoelectric conversion unit (the photodiode PD2) and disperses light transmitted through the first photoelectric conversion unit (the photoelectric conversion unit 52). The first color splitter (the color splitter CS1) makes light in the second wavelength region (the red region) incident on the second photoelectric conversion unit (the photodiode PD1) near the first color splitter (the color splitter CS1) and bends light in the third wavelength region (the blue region) toward the third photoelectric conversion unit adjacent to the first color splitter (the color splitter CS1). The second color splitter (the color splitter CS2) makes light in the third wavelength region (the blue region) incident on the third photoelectric conversion unit (the photodiode PD2) near the second color splitter (the color splitter CS2), and bends light in the second wavelength region (the red region) toward the second photoelectric conversion unit adjacent to the second color splitter (the color splitter CS2).

Consequently, the sensitivity of the photodiodes PD1 and PD2 located on the opposite side of the light incident side can be improved.

In the solid-state imaging element 1 according to the embodiment, the first color splitter (the color splitter CS1) and the second color splitter (the color splitter CS2) have a meta-surface structure.

Consequently, the sensitivity of the photodiodes PD1 and PD2 located on the side opposite of the light incident side can be further improved.

The solid-state imaging element 1 according to the embodiment further includes the first color filter (the color filter 43R) and the second color filter (the color filter 43B). The first color filter (the color filter 43R) is disposed between the first color splitter (the color splitter CS1) and the second photoelectric conversion unit (the photodiode PD1) and selectively transmits light in the second wavelength region (the red region). The second color filter (the color filter 43B) is disposed between the second color splitter (the color splitter CS2) and the third photoelectric conversion unit (the photodiode PD2) and selectively transmits light in the third wavelength region (the blue region).

Consequently, occurrence of color mixture in the photodiodes PD1 and PD2 can be suppressed.

In the solid-state imaging element 1 according to the embodiment, the first wavelength region is a green region and the second wavelength region and the third wavelength region are either the blue region or the red region.

Consequently, occurrence of color mixture in the photodiodes PD1 and PD2 can be suppressed.

The solid-state imaging element 1 according to the embodiment further includes the light blocking wall 42. The light blocking wall 42 is disposed between the first color splitter (the color splitter CS1) and the second color splitter (the color splitter CS2) and the second photoelectric conversion unit (the photodiode PD1) and the third photoelectric conversion unit (the photodiode PD2). The light blocking wall 42 is provided to surround the second photoelectric conversion unit (the photodiode PD1) or the third photoelectric conversion unit (the photodiode PD2) in a plan view.

Consequently, occurrence of color mixture in the photodiodes PD1 and PD2 can be suppressed.

### [Electronic Equipment]

Note that the present disclosure is not limited to the application to the solid-state imaging element. That is, the present disclosure is applicable to, besides the solid-state imaging element, all kinds of electronic equipment including solid-state imaging elements such as a camera module, an imaging device, a mobile terminal device having an imaging function, or a copying machine using a solid-state imaging element in an image reading section.

Examples of such an imaging device include a digital still camera and a video camera. Examples of such a portable terminal device having the imaging function include a smartphone and a tablet terminal.

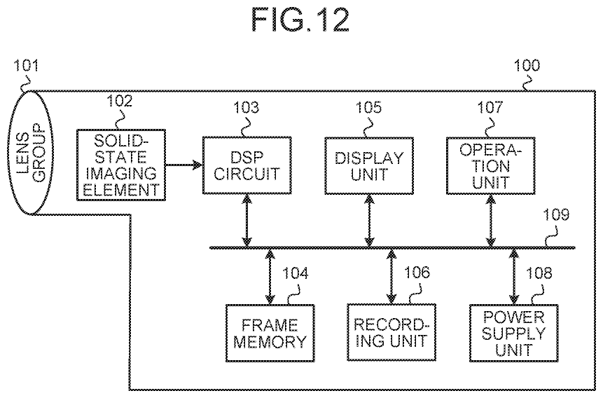

FIG. 12 is a block diagram illustrating a configuration example of an imaging device functioning as a electronic equipment 100 to which the technique according to the present disclosure is applied. The electronic equipment 100 illustrated in FIG. 12 is, for example, electronic equipment such as an imaging device such as a digital still camera or a video camera or a portable terminal device such as a smartphone or a tablet terminal.

In FIG. 12, the electronic equipment 100 includes a lens group 101, a solid-state imaging element 102, a DSP circuit 103, a frame memory 104, a display unit 105, a recording unit 106, an operation unit 107, and a power supply unit 108.

In the electronic equipment 100, the DSP circuit 103, the frame memory 104, the display unit 105, the recording unit 106, the operation unit 107, and the power supply unit 108 are connected to one another via a bus line 109.

The lens group 101 captures incident light (image light) from a subject and forms an image on an imaging surface of the solid-state imaging element 102. The solid-state imaging element 102 corresponds to the solid-state imaging element 1 according to the embodiment explained above and converts a light amount of the incident light imaged on the imaging surface by the lens group 101 into an electrical signal in units of pixels and outputs the electrical signal as a pixel signal.

The DSP circuit 103 is a camera signal processing circuit that processes a signal supplied from the solid-state imaging element 102. The frame memory 104 temporarily retains, in units of frames, the image data processed by the DSP circuit 103.

The display unit 105 includes, for example, a panel type display device such as a liquid crystal panel or an organic EL (Electro Luminescence) panel and displays a moving image or a still image captured by the solid-state imaging element 102. The recording unit 106 records image data of the moving image or the still image captured by the solid-state imaging element 102 on a recording medium such as a semiconductor memory or a hard disk.

The operation unit 107 issues operation commands for various functions of the electronic equipment 100 according to operation by a user. The power supply unit 108 supplies, as appropriate, various power sources serving as operation power sources for the DSP circuit 103, the frame memory 104, the display unit 105, the recording unit 106, and the operation unit 107 to these supply targets.

In the electronic equipment 100 configured as explained above, by applying the solid-state imaging element 1 in the embodiments explained above as the solid-state imaging element 102, it is possible to improve the sensitivity of the photodiodes PD1 and PD2 located on the side opposite of the light incident side.

Although the embodiments of the present disclosure are explained above, the technical scope of the present disclosure is not limited to the embodiments explained above per se. Various changes are possible without departing from the gist of the present disclosure. Components in different embodiments and modifications may be combined as appropriate.

The effects described in the present specification are only examples and are not limited. There may be other effects.

Note that the present technique can also take the following configurations.

(1)

A solid-state imaging element, comprising
a first photoelectric conversion unit that includes a photoelectric conversion layer made of an organic material and photoelectrically converts light in a first wavelength region;
a second photoelectric conversion unit that is disposed on an opposite side of a light incident side with respect to the first photoelectric conversion unit and photoelectrically converts light in a second wavelength region different from the first wavelength region;
a third photoelectric conversion unit that is disposed side by side with the second photoelectric conversion unit and photoelectrically converts light in a third wavelength region different from the first wavelength region and the second wavelength region;
a first color splitter that is disposed between the first photoelectric conversion unit and the second photoelectric conversion unit and disperses light transmitted through the first photoelectric conversion unit; and
a second color splitter that is disposed between the first photoelectric conversion unit and the third photoelectric conversion unit and disperses the light transmitted through the first photoelectric conversion unit; wherein
the first color splitter makes the light in the second wavelength region incident on the second photoelectric conversion unit near the first color splitter and bends the light in the third wavelength region toward the third photoelectric conversion unit adjacent to the first color splitter, and
the second color splitter makes the light in the third wavelength region incident on the third photoelectric conversion unit near the second color splitter and bends the light in the second wavelength region toward the second photoelectric conversion unit adjacent to the second color splitter.

(2)

The solid-state imaging element according to the above (1), wherein the first color splitter and the second color splitter have a meta-surface structure.

(3)

The solid-state imaging element according to the above (1) or (2), further comprising:
a first color filter that is disposed between the first color splitter and the second photoelectric conversion unit and selectively transmits the light in the second wavelength region; and
a second color filter that is disposed between the second color splitter and the third photoelectric conversion unit and selectively transmits the light in the third wavelength region.

(4)

The solid-state imaging element according to any one of the above (1) to (3), wherein
the first wavelength region is a green region, and
the second wavelength region and the third wavelength region are either a blue region or a red region.

(5)

The solid-state imaging element according to any one of the above (1) to (4), further comprising a light blocking wall disposed between the first color splitter and the second color splitter, and the second photoelectric conversion unit and the third photoelectric conversion unit, and provided to surround the second photoelectric conversion unit or the third photoelectric conversion unit in a plan view.

(6)

Electronic equipment, comprising:
a solid-state imaging element;
an optical system that captures incident light from a subject and forms an image on an imaging surface of the solid-state imaging element; and
a signal processing circuit that performs processing on an output signal from the solid-state imaging element, wherein
the solid-state imaging element includes:
a first photoelectric conversion unit that includes a photoelectric conversion layer made of an organic material and photoelectrically converts light in a first wavelength region;
a second photoelectric conversion unit that is disposed on an opposite side of a light incident side with respect to the first photoelectric conversion unit and photoelectrically converts light in a second wavelength region different from the first wavelength region;
a third photoelectric conversion unit that is disposed side by side with the second photoelectric conversion unit and photoelectrically converts light in a third wavelength region different from the first wavelength region and the second wavelength region;
a first color splitter that is disposed between the first photoelectric conversion unit and the second photoelectric conversion unit and disperses light transmitted through the first photoelectric conversion unit; and
a second color splitter that is disposed between the first photoelectric conversion unit and the third photoelectric conversion unit and disperses the light transmitted through the first photoelectric conversion unit,
the first color splitter makes the light in the second wavelength region incident on the second photoelectric conversion unit near the first color splitter and bends the light in the third wavelength region toward the third photoelectric conversion unit adjacent to the first color splitter, and
the second color splitter makes the light in the third wavelength region incident on the third photoelectric conversion unit near the second color splitter and bends the light in the second wavelength region toward the second photoelectric conversion unit adjacent to the second color splitter.

(7)

The electronic equipment according to the above (6), wherein the first color splitter and the second color splitter have a meta-surface structure.

(8)

The electronic equipment according to the above (6) or (7), wherein the solid-state imaging element further includes:
a first color filter that is disposed between the first color splitter and the second photoelectric conversion unit and selectively transmits the light in the second wavelength region; and
a second color filter that is disposed between the second color splitter and the third photoelectric conversion unit and selectively transmits the light in the third wavelength region.

(9)

The electronic equipment according to any one of the above (6) to (8), wherein
the first wavelength region is a green region, and
the second wavelength region and the third wavelength region are either a blue region or a red region.

(10)

The electronic equipment according to any one of the above (6) to (9), wherein the solid-state imaging element further includes a light blocking wall disposed between the first color splitter and the second color splitter and the second photoelectric conversion unit and the third photoelectric conversion unit and provided to surround the second photoelectric conversion unit or the third photoelectric conversion unit in a plan view.

### REFERENCE SIGNS LIST

1 SOLID-STATE IMAGING ELEMENT
10 PIXEL ARRAY UNIT
42 LIGHT BLOCKING WALL
43R COLOR FILTER (EXAMPLE OF FIRST COLOR FILTER)
43B COLOR FILTER (EXAMPLE OF SECOND COLOR FILTER)
44 LOW REFRACTIVE INDEX LAYER
44a, 44b CONVEX PORTION
45 HIGH REFRACTIVE INDEX LAYER
52 PHOTOELECTRIC CONVERSION UNIT (EXAMPLE OF FIRST PHOTOELECTRIC CONVERSION UNIT)
52b PHOTOELECTRIC CONVERSION LAYER
100 ELECTRONIC EQUIPMENT
CS1 COLOR SPLITTER (EXAMPLE OF FIRST COLOR SPLITTER)
CS2 COLOR SPLITTER (EXAMPLE OF SECOND COLOR SPLITTER)
PD1 PHOTODIODE (EXAMPLE OF SECOND PHOTOELECTRIC CONVERSION UNIT)
PD2 PHOTODIODE (EXAMPLE OF THIRD PHOTOELECTRIC CONVERSION UNIT)

1. A solid-state imaging element, comprising
a first photoelectric conversion unit that includes a photoelectric conversion layer made of an organic material and photoelectrically converts light in a first wavelength region;
a second photoelectric conversion unit that is disposed on an opposite side of a light incident side with respect to the first photoelectric conversion unit and photoelectrically converts light in a second wavelength region different from the first wavelength region;
a third photoelectric conversion unit that is disposed side by side with the second photoelectric conversion unit and photoelectrically converts light in a third wavelength region different from the first wavelength region and the second wavelength region;
a first color splitter that is disposed between the first photoelectric conversion unit and the second photoelectric conversion unit and disperses light transmitted through the first photoelectric conversion unit; and
a second color splitter that is disposed between the first photoelectric conversion unit and the third photoelectric conversion unit and disperses the light transmitted through the first photoelectric conversion unit; wherein
the first color splitter makes the light in the second wavelength region incident on the second photoelectric conversion unit near the first color splitter and bends the light in the third wavelength region toward the third photoelectric conversion unit adjacent to the first color splitter, and
the second color splitter makes the light in the third wavelength region incident on the third photoelectric conversion unit near the second color splitter and bends the light in the second wavelength region toward the second photoelectric conversion unit adjacent to the second color splitter.

2. The solid-state imaging element according to claim 1, wherein the first color splitter and the second color splitter have a meta-surface structure.

3. The solid-state imaging element according to claim 1, further comprising:
a first color filter that is disposed between the first color splitter and the second photoelectric conversion unit and selectively transmits the light in the second wavelength region; and
a second color filter that is disposed between the second color splitter and the third photoelectric conversion unit and selectively transmits the light in the third wavelength region.

4. The solid-state imaging element according to claim 1, wherein
the first wavelength region is a green region, and
the second wavelength region and the third wavelength region are either a blue region or a red region.

5. The solid-state imaging element according to claim 1, further comprising a light blocking wall disposed between the first color splitter and the second color splitter, and the second photoelectric conversion unit and the third photoelectric conversion unit, and provided to surround the second photoelectric conversion unit or the third photoelectric conversion unit in a plan view.

6. Electronic equipment, comprising:
a solid-state imaging element;
an optical system that captures incident light from a subject and forms an image on an imaging surface of the solid-state imaging element; and
a signal processing circuit that performs processing on an output signal from the solid-state imaging element, wherein
the solid-state imaging element includes:
a first photoelectric conversion unit that includes a photoelectric conversion layer made of an organic material and photoelectrically converts light in a first wavelength region;
a second photoelectric conversion unit that is disposed on an opposite side of a light incident side with respect to the first photoelectric conversion unit and photoelectrically converts light in a second wavelength region different from the first wavelength region;
a third photoelectric conversion unit that is disposed side by side with the second photoelectric conversion unit and photoelectrically converts light in a third wavelength region different from the first wavelength region and the second wavelength region;
a first color splitter that is disposed between the first photoelectric conversion unit and the second photoelectric conversion unit and disperses light transmitted through the first photoelectric conversion unit; and
a second color splitter that is disposed between the first photoelectric conversion unit and the third photoelectric conversion unit and disperses the light transmitted through the first photoelectric conversion unit,
the first color splitter makes the light in the second wavelength region incident on the second photoelectric conversion unit near the first color splitter and bends the light in the third wavelength region toward the third photoelectric conversion unit adjacent to the first color splitter, and
the second color splitter makes the light in the third wavelength region incident on the third photoelectric conversion unit near the second color splitter and bends the light in the second wavelength region toward the second photoelectric conversion unit adjacent to the second color splitter.
